(19) United States
(12) Patent Application Publication
(10) Pub. No.: US 2025/0227859 A1
(43) Pub. Date: Jul. 10, 2025

(54) METHOD AND APPARATUS FOR RETROFITTING BATTERY-OPERATED DEVICES

(71) Applicant: Universal Electronics Inc., Scottsdale, AZ (US)

(72) Inventors: Rex Xu, Foothill Ranch, CA (US); Kuldip Singh Johal, Wokingham (GB); Steven McAllister, London (GB)

(21) Appl. No.: 19/001,014

(22) Filed: Dec. 24, 2024

Related U.S. Application Data
(63) Continuation-in-part of application No. 18/747,148, filed on Jun. 18, 2024.
(60) Provisional application No. 63/619,134, filed on Jan. 9, 2024.

(51) Int. Cl. H05K 5/00; H01M 10/46; H01M 50/247; H01M 50/271; H05K 5/03

(52) U.S. Cl. CPC H05K 5/0086; H01M 10/46; H01M 50/247; H01M 50/271; H05K 5/03; H01M 2220/30

(57) ABSTRACT

A module for providing power to a battery-operated device having a body in which is formed a battery compartment and a cover having one or more first elements cooperable with one or more second elements provided to the body for releasably positioning the cover over the battery compartment. The module has an energy-generating surface, an energy storage device coupled to the energy-generating surface, and a storage device cover positionable over the energy-generating surface. The storage device cover has one or more third elements cooperable with the one or more second elements provided to the body for releasably positioning the module cover over the battery compartment when the energy storage device is positioned within the battery compartment in engagement with one or more electrical contacts positioned within the battery compartment.

### RELATED APPLICATION INFORMATION

This application claims the benefit of U.S. application Ser. No. 18/747,148, filed on claims Jun. 18, 2024, which application claims the benefit of U.S. Application No. 63/619,134, filed on Jan. 9, 2024, which applications are incorporated herein by reference in their entireties.

### BACKGROUND

Battery-operated devices are ubiquitous. They include devices such as remote controls, electronic games and toys, communication devices such as cell phones, walkie-talkies, etc., and a myriad of other devices. Some devices may be powered by rechargeable batteries, while others require standard, non-rechargeable batteries, typically ranging in size from coin-cell, to AAA, to D-sized batteries.

While batteries enable the convenience of operating a device for typically long periods of time without having to be physically connected to a power source, their main drawback is that they will always need to be replaced at some time interval, depending on its power consumption and time of use. Regarding non-rechargeable batteries, this means replacing dead batteries with fresh ones and having to dispose of the dead batteries, typically in a landfill. Regarding rechargeable batteries, while more eco-friendly, these batteries still suffer the inconvenience of having to be recharged and sometimes having to be removed and replaced.

To solve some of these problems, commonly assigned US Publication No. 2024/0097063, which is incorporated herein by reference in its entirety, describes devices that are to be constructed with one or more energy harvesting features. While these devices work for their intended purpose, a need for retrofitting devices that were constructed to use disposable and/or rechargeable batteries with energy harvesting features continues to exist.

### SUMMARY

The follow generally describes a battery-operated device to which is coupled a module having one or more energy harvesting features. More particularly, the following describes a module for providing power to a battery-operated device having a body in which is formed a battery compartment and a cover having one or more first elements cooperable with one or more second elements provided to the body for releasably positioning the cover over the battery compartment. The module has an energy-generating surface, an energy storage device coupled to the energy-generating surface, and a storage device cover positionable over the energy-generating surface. The storage device cover has one or more third elements cooperable with the one or more second elements provided to the body for releasably positioning the module cover over the battery compartment when the energy storage device is positioned within the battery compartment in engagement with one or more electrical contacts positioned within the battery compartment.

A better appreciation of the objects, advantages, features, properties, and relationships of the described controlling devices will be obtained from the following detailed description and accompanying drawings which set forth illustrative embodiments which are indicative of the various ways in which the principles described hereinafter may be employed.

### BRIEF DESCRIPTION OF THE DRAWINGS

For use in better understanding the example energy harvesting modules adapted for use with battery powered devices that are described hereinafter reference may be had to the following drawings in which:

FIG. 1A is a top perspective view of a battery-powered device, particularly showing user input elements;

FIGS. 1B and 1C are bottom perspective views of the battery-powered device, particularly showing a battery compartment;

FIGS. 1D and 1F illustrate an energy harvesting system cooperable with the battery compartment of the battery-powered device;

FIGS. 1E-1I illustrate further energy harvesting system cooperable with the battery compartment of the battery-powered device;

FIG. 2A illustrate a top perspective view and a bottom perspective view of a further example battery-powered device;

FIG. 2B illustrate a top perspective view and a bottom perspective view of the battery-powered device having an energy harvesting system attached thereto;

FIG. 2C illustrates an exploded view of the battery-powered device of FIG. 2B;

FIGS. 3A-3G illustrate a new, ornamental design for a battery-powered device with an energy harvesting, battery system;

FIGS. 4A-4G illustrate a new, ornamental design for an energy harvesting, battery system;

FIGS. 5A-5G illustrate a new, ornamental design for a cover of an energy harvesting, battery system;

FIG. 6A illustrates a bottom, perspective view of an OEM remote control with the original battery compartment cover engaged with the remote control main body;

FIG. 6B illustrates a bottom, perspective view of the remote control of FIG. 6A with the original battery compartment cover removed from the remote control maid body;

FIG. 6C illustrates a bottom, perspective view of the remote control of FIG. 6A with a battery replacement module installed in the battery compartment;

FIG. 6D illustrates a bottom, perspective view of the remote control of FIG. 6A with an energy harvesting, battery system cover attached to the remote control main body;

FIG. 7A illustrates a top, plan view on the remote control of FIG. 6A;

FIG. 7B illustrates a side view of the remote control of FIG. 6A including the original battery compartment cover engaged with the remote control main body;

FIG. 7C illustrates a side view of the example remote control of FIG. 6A with the original battery compartment cover removed and a battery replacement module installed within the battery compartment;

FIG. 7D illustrates a side view of the example remote control of FIG. 6A with an energy harvesting, battery system cover attached to the remote control main body;

FIG. 7E illustrates a bottom, plan view of the remote control of FIG. 7D;

FIG. 8A illustrates an electronic device and a battery replacement module adapted for insertion into a battery compartment of the electronic device;

FIG. 8B illustrates a step for installing the battery replacement module within the battery compartment of the electronic device;

FIG. 8C illustrates the battery replacement module installed within the battery compartment of the electronic device;

FIG. 9 illustrates an exploded view of an example battery replacement module;

FIG. 10A illustrates a bottom, plan view of the battery replacement module of FIG. 9;

FIG. 10B illustrates a side view of the battery replacement module of FIG. 9;

FIG. 10C illustrates a top, plan view of the battery replacement module of FIG. 9;

FIG. 11 illustrates a method for installing the battery replacement module of FIG. 9 in a remote control battery compartment of an example remote control;

FIG. 12A illustrates a bottom, plan view of the remote control of FIG. 11;

FIG. 12B illustrates a side view of the remote control of FIG. 11 with an energy harvesting, battery system cover attached to the remote control main body;

FIG. 12C illustrates a top, plan view of the remote control of FIG. 12B;

FIG. 13 illustrates an exploded view of an example battery replacement module;

FIG. 14A illustrates a top, plan view of the battery replacement module of FIG. 13;

FIG. 14B illustrates a side view of the battery replacement module of FIG. 13;

FIG. 14C illustrates a bottom, plan view of the battery replacement module of FIG. 13; and

FIG. 15 illustrates a method for installing the battery replacement module of FIG. 13 in a remote control battery compartment of an example remote control.

### DETAILED DESCRIPTION

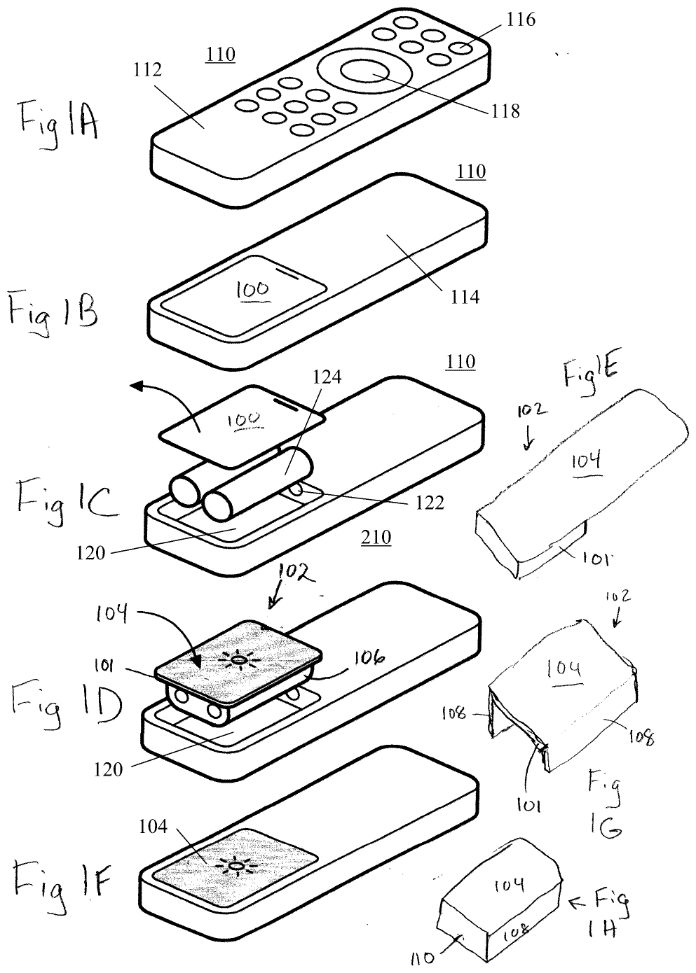

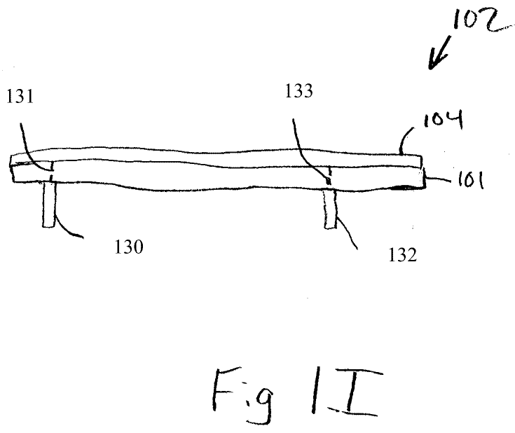

FIGS. 1A through 1I illustrate an example battery-operated device in the form of a television remote control, particularly an original equipment manufacturer (OEM) remote control, and examples of energy harvesting systems usable to provide power to the example remote control. While illustrated as being utilized in connection with a remote control, it is to be understood that the concepts described herein could be applied to virtually any type of battery-operated device.

FIG. 1A is a perspective view of an example battery powered device in the form on a television remote control 110. The top portion 112 of the remote control 110 comprises a user interface. In this example, the user interface comprises a key matrix having a plurality of hard keys 116 and a circular directional button 118. The user interface can equally include a touch screen display providing soft keys, capacitive input elements, or the like without limitation. The user interface is operated by an individual to perform certain actions, particularly to cause a transmission of one or more commands using a protocol/format that will be understood by one or more intended target devices. The remote control 110 in the illustrated example is thus usable to command a television to power on or off, change channels, adjust the volume, etc.

FIG. 1B is a perspective view of the television remote control 110 as shown in FIG. 1A shown in reverse orientation, i.e., a view that highlights a back surface 114 of the television remote control 110 opposite the top surface 112 where the user interface is typically located. Shown in this view is a removable battery cover 100 installed over a battery compartment 120. The battery compartment 120 holds one or more batteries 124 that power the television remote control 110. In this example, the batteries are installed in parallel, meaning that the positive and negative terminals of the battery face in the same direction. The battery compartment 120 additionally includes electrical contacts 122 that function to couple the one or more batteries 124 installed within the battery compartment 120 to the electrical components, such as a processor, transmitter, etc., of which the remote control 110 is comprised. The electrical contacts 120 can further include a spring element for the purpose of ensuring a good coupling between the electrical contacts of the one or more batteries 124 and the electrical contacts 120. In addition, the use of a spring element can assist in maintaining the one or more batteries 124 within the battery compartment 120. During normal operation, removable battery cover 100 is installed over the battery compartment 120 as shown.

To maintain the battery cover 100 in an installed position over the battery compartment 120, the remote control 110 and the battery compartment cover 100 can be provided with cooperating features. For example, the battery cover 100 and the remote control 110 can be provided with a cooperating tongue and groove features that allows the battery cover 100 to be slidingly engaged with bottom surface 114 of the remote control 110 over the battery compartment 120. In further examples, the battery cover 100 can include a tab feature that is intended to engage with a cooperating interior surface of the bottom surface 114 of the remote control 110. The tab feature can additionally include a latch or hook that is cooperable with the underside surface where a slight depression of the cover 100 can be utilized to displace the hook from it cooperating engagement surface. In still further examples, the battery cover 100 can be releasably snap fit to the remote control 110.

FIG. 1C shows the same perspective view of the television remote control 110 as shown in FIG. 1B, with the removable battery cover 100 as well as the two cylindrical batteries 124 that are normally stored within the battery compartment 120 being removed. The removal of these element is required in those instances where the subject energy harvesting module 104 is intended to be placed within the battery compartment. In other examples, removal of battery cover 100 and the batteries will not be necessary.

FIG. 1D shows the same perspective view of the television remote control 110 as shown in FIGS. 1B and 1C, with the exception that removable battery cover 100 and the existing batteries are in the process of being replaced by an energy-harvesting battery system 102. In this example, the energy harvesting battery system 102 comprising a substrate 101, an energy-generating surface 104 and one or more energy storage devices 106 which are coupled to the energy-generating surface 104. The energy generating surface 104 will include or be coupled to one or more elements that are described in US 2024/0097063, e.g., a PV active area, PCB, and a lens system as needed. Substrate 101 is provided to support the energy-generating surface 104 and to act as a replacement battery cover. For this purpose substrate 101 is constructed of a hard, durable material, such as plastic, PVC, or the like, and is sized and shaped to substantially match the physical dimensions of removable battery cover 100 such that removable energy-producing system 102 can be installed over the battery compartment and secured in place via known techniques, such as by screwing, latching, etc. Typically, removable energy-producing battery system 102 comprises a substrate 101 that uses the same securing technique as used by removable battery cover 100.

In one example, substrate 101 and energy-generating surface 104 are combined into a single unit. In other examples, energy-generating surface 104 is affixed, installed, or otherwise placed on a top surface of substrate 101, i.e., the surface of substrate 101 that would normally be exposed to light.

As noted, energy-generating surface 104 comprises photo-voltaic cells capable of producing energy when exposed to light, such as monocrystalline, polycrystalline, thin-film, perovskite, organic, and/or passivated emitter and rear cell solar cells. In another example, energy-generating surface 104 comprises RF harvesting circuitry. In yet another example, energy-generating surface 104 comprises wireless inductive charging technology, for example, in accordance with the Qi wireless inductive charging technology standard promulgated by the Wireless Power Consortium. In a further example, the energy-generating surface 104 includes one or more kinetic energy harvesting devices. In any case, the size and shape of energy-generating surface 104 is at least approximately equal to the size and shape of substrate 101 in order to maximize the energy-harvesting features usable within the system 102.

In another example, shown in FIG. 1E, the size and shape of energy-generating surface 104 may extend beyond the size and shape of substrate 101. In the example shown in FIG. 1E, the width of energy-generating surface 104 is approximately equal to a width of substrate 101, however, the length of energy-generating surface 104 extends significantly longer than a length of substrate 101 as well as the length of the original battery compartment 120. In this example, substrate 101 is still installable over the battery compartment while energy-generating surface 104 extends past the battery compartment and, in some examples, matches a size and shape of the bottom surface 114 of the television remote control 110. In other embodiments, the size and shape of energy-generating surface 104 may be smaller than the size and shape of the bottom surface 114 of the television remote control 110.

When energy-generating surface 104 is exposed to light, ambient RF energy, movement, and/or inductive energy, depending on implementation, it produces energy, typically in the form of a voltage and current, which is provided to one or more energy storage devices 106. In the example shown in FIG. 1D, two such energy storage devices 106 are shown, although in other embodiments, a greater or lesser number of energy storage devices 106 may be used, depending on capacity, size, cost, etc. The energy produced by energy-generating surface 104 is used to charge the one or more energy storage devices 106. Each energy storage device 106 may comprise one or more capacitors, one or more inductors or one or more rechargeable batteries. Additional circuitry (not shown) may be desirable depending on what type of energy storage device is used. For example, additional circuitry may comprise one or more resistors, transistors, capacitors, active components, diodes, etc. Additional circuitry may additionally, or alternatively, comprise a USB port for charging the one or more energy storage devices 106 in the event that insufficient energy harvesting is available due to low/no light/ambient RF/inductive energy and/or high usage, etc.

The energy storage devices 106 are coupled to electrical connectors that are arranged within the system 102 to engage with the electrical connectors 122 within the battery compartment 120. An indicator for conveying a state of charge of the one or more energy storage devices 106, such as one or more LED may also be provided. Any such additional circuitry would typically be mounted on an under surface of substrate 101, i.e., a surface of substrate 101 that faces the battery compartment, in proximity to the one or more energy storage devices 106, so that the one or more energy storage devices 106 and the additional circuitry all fit within the battery compartment when energy-producing battery system 102 is installed in place. The charge indicator (when used) may be mounted to energy-producing battery system 102 such that it is viewable on the surface of energy-producing battery system 102. In other examples, the battery system 102 may communicate status information to another device, using any convenient transmission mechanism, whereby one of more conditions associated with the battery system may be communicated to the user.

The one or more energy storage devices 106 are designed to power the television remote control 110 for a desired amount of time without energy-generating surface 104 having to be continually exposed to light, ambient RF energy or inductive energy, depending on implementation. The storage capacity may allow for between 12 and 48 hours of use or more. In an example where the television remote control is designed to accept two alkaline or NiMH AA batteries, the one or more energy storage devices 106 may be selected to store 21,600 coulombs of charge, equal to about 4,000 to 6,000 mAh at a voltage between 1.2 V and 1.5V. Depending on the number and type of batteries normally required to power the television remote control, the capacity of the one or more energy storage devices 106 may be greater, or less than, the capacity of two AA batteries.

FIG. 1F is a perspective view of the television remote control 110 shown in FIG. 1D, with energy-producing system 102 installed in place over the battery compartment. The size and shape of the one or more energy storage devices 106 is such that they fit within the battery compartment (in some cases, matching a size and shape of the original battery(s) while in other embodiments, smaller than the original battery(s) so that they fit within the battery compartment) and, additionally, are positioned with respect to substrate 101 such that when installed into the battery compartment, contact is made between the one or more energy storage devices 106 and battery terminals 122 located within the battery compartment.

FIG. 1G is a perspective view of another example of energy-producing battery system 102, comprising at least one side panel 108. In the example shown in FIG. 1G, two side panels 108 are used, each one spanning an approximate length of substrate 101. Each side panel 108 extends downwardly from the longitudinal edges of substrate 101 and, in some embodiments, each side panel 108 is sized to approximately match a thickness of the television remote control. In other words, when energy-producing battery system 102 is installed onto the battery compartment, each side panel 108 covers a portion of a side of the television remote control 110. In some examples, energy-generating surface 104 is applied to substrate 101 as well as one or both side panels 108. In another embodiment, energy-generating surface 104 is not applied to substrate 101 and relies only on one or both side panels 108 to generate energy for storage by one or more energy storage devices 106. In a related embodiment, the embodiment shown in FIG. 1G can be combined with the embodiment shown in FIG. 1E, i.e., energy-generating surface 104 can be applied to one or both side panels 108 as well as extend past the size and shape of substrate 101 as shown in FIG. 1E. In another related embodiment, energy-generating surface 104 may, in addition to the side panels 108 shown in FIG. 1G, further comprise an end surface 110 that extends downwards over an end portion of the television remote control 110. This example is shown in FIG. 1H, end surface 110 may comprise energy-generating surface 104 for production of energy when and surface 110 is exposed to light, exposed to ambient RF energy or inductive energy, depending on implementation.

In another example, energy-generating surface 104 may be affixed on a top surface of the television remote control and electrically coupled to one or more energy storage devices 106 via substrate 101. This example allows charging while the television remote control 110 is facing upwards. In some examples, energy-generating surface 104 may be placed on more than one surface of the television remote control 110. For example, and energy-generating surface 104 may be affixed to the top surface 112 of the television remote control 110 and coupled electrically to the one or more energy storage devices 106, while additionally comprising another energy-generating surface 104 affixed to substrate 101, and/or sides 108 and/or and surface 110.

FIG. 1I is a side view of another example of an energy-producing battery system 102, used in an embodiment where the television remote control contains rechargeable batteries that are normally charged via a charge port, i.e., a barrel connector, USB port, etc. In this example, the original, rechargeable battery(s) of the television remote control 110 are not replaced. Rather, energy-producing battery system 102 lacks any energy storage devices and is configured to replace the original battery cover and then charge the existing battery(s) via an energy-generating surface 104 affixed, or part of, substrate 101.

In the example of FIG. 1I, energy-producing battery system 102 is the same or similar to the energy-producing battery system 102 as shown in FIG. 1D, comprising a substrate 101 and energy-generating surface 104, where substrate 101 substantially matches the size and shape of original battery cover 100, and, in this example, energy-generating surface 104 substantially matches the size and shape of substrate 101. However, unlike the energy-producing battery system 102 as shown in FIG. 1D, energy-producing battery system 102 in this example comprises at least two conductive battery charging terminals 112 and 114 extending downwards from an undersurface of substrate 101. The terminals are spaced apart from each other such that they connect with the plus side and the minus side, respectively, of the existing battery(s). Thus, when the original battery cover is replaced by energy-producing battery system 102, the terminals 130 and 132 connect to the respective battery terminals of the existing, rechargeable battery(s) inside the battery compartment. The existing, rechargeable battery(s) are then charged by energy-generating surface 104 when exposed to light, RF energy or inductive energy, depending on implementation. Charge generated by energy-generating surface 104 is provided to each terminal 130 and 132 via conductors 131 and 133, respectively.

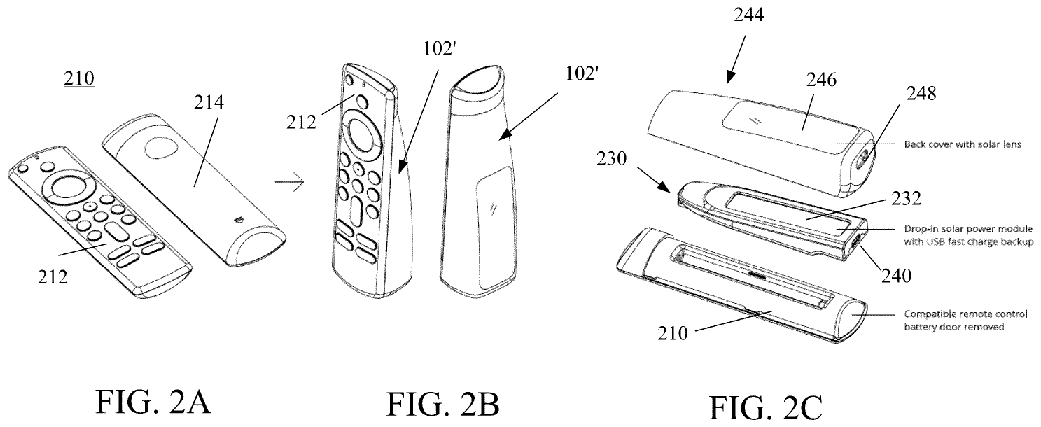

Turning to FIGS. 2A-2C another example OEM remote control 210 is illustrated. As before the remote control 210 has a front surface 212 supporting user input elements, a cover 214, and a battery compartment 216 having electrical contacts 218A and 218B located on opposed sides of the battery compartment 216. Electrical contact 218B in this example is in the form of a spring and the spring functions to bias batteries inserted into the battery compartment 216 toward electrical contact 218A. It will be appreciated that, in this example, batteries are installed in series within the battery compartment 216 between the electrical contacts 218A and 218B. The cover 214 is proved with tongue surfaces that are intended to mate with grooves 220 formed in the remote control 210 thus allowing the cover 214 to be slid into place over the battery compartment 216.

The energy-producing battery system 102′ in this example includes a drop-in battery module 230. The drop-in battery module 230 includes one or more of the elements described previously with respect to energy-generating surface 104 and includes one or more battery storage devices coupled to contacts that are arranged to mate with contacts 218A and 218B when the drop-in battery module 230 is placed into the battery compartment 216. In the illustrated example, the drop-in battery module 230 includes a solar power energy collecting surface 232 which is coupled to the battery storage devices. The drop-in battery module 230 is larger than the battery compartment 230 in the illustrated example to maximize the light collecting surface 232. While not required, the drop-in battery module 230 includes a USB port 240 for allowing the drop-in battery module 230 to be charged from an electrical source as described previously. The USB port 240 will be positioned outside of the battery compartment 230 when the drop-in battery module 230 is inserted in the battery compartment 216. This will allow the drop-in battery module 230 to be charged without requiring the removal of the battery module 230 from the battery compartment.

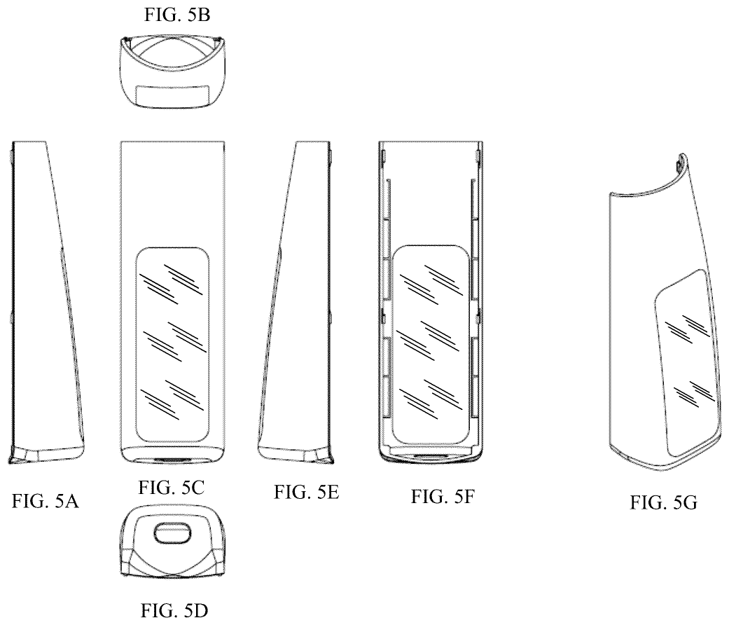

For maintaining the drop-in battery module 230 within the battery compartment the energy-producing battery system 102′ includes a cover portion 244. The cover portion 240 includes a transparent window 246 that will be positioned over the light capturing surface 232 of the drop-in battery module 230. The transparent window 246 can include one or more lenses for maximizing and/or focusing light that is directed to the light capturing surface 232. The cover portion 244 may also include an opening 248 to allow access to the USB port 240. The cover portion 244 is provided with tongues (shown in FIG. 5F) for engaging with the grooves 220 provided to the remote control 210 body. The cover portion 244 can thus be slidably engaged with the remote control 210 in place of the cover 214. The cover portion 244, when so engaged with the body, will maintain the drop-in battery module 230 in secure engagement with the battery contacts 218A and 218B. The cover may provide a tight fight with the module when the module is inserted into the compartment. The cover may also be made of a somewhat flexible material to apply a biasing force upon the module when the module is inserted into the battery compartment. The cover may also include biasing elements, such as a spring, wedge, cushion, or the like to apply a force upon the drop-in battery module 230 in the direction of the battery compartment 216 if needed. When attached to the remote control 210 in place of the cover 214, the energy-producing battery system 102′ will be coupled to the remote control 210 as shown in FIG. 2B.

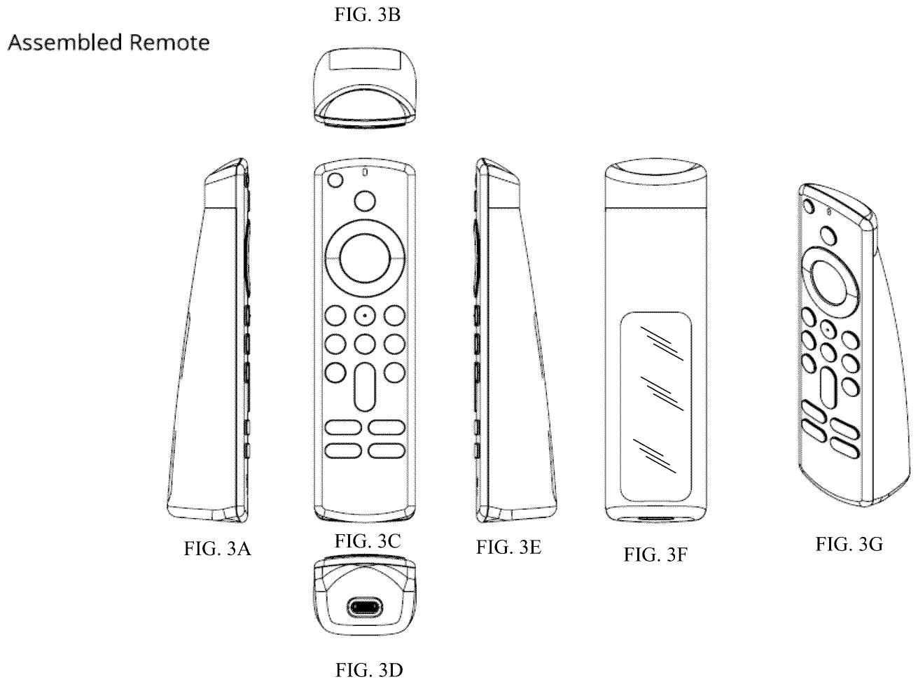

More particularly, FIGS. 3A-3G illustrate the new, ornamental design that will result when the energy-producing battery system 102′ is coupled to the remote control 210. FIG. 3A is a right side elevational view showing the new design; FIG. 3B is front elevational view showing the new design; FIG. 3C is a top plan view showing the new design; FIG. 3D is a rear elevational view showing the new design, FIG. 3E is a right side elevational view showing the new design, FIG. 3F is a bottom plan view; and FIG. 3G is a perspective view.

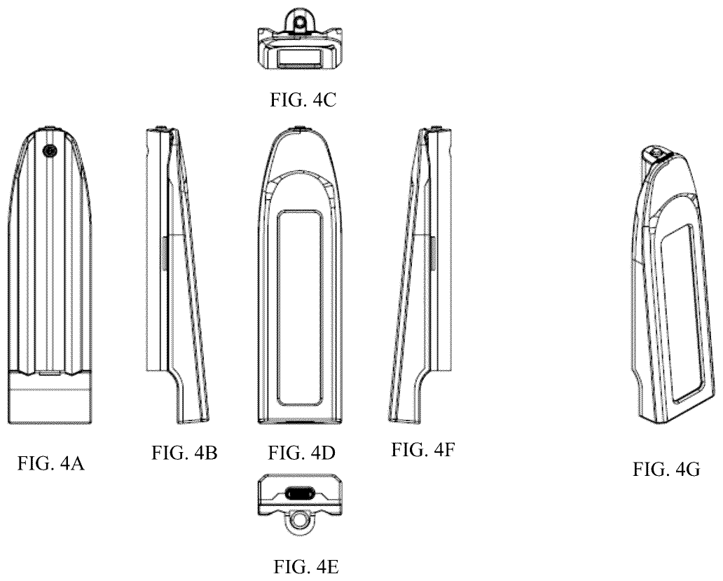

FIGS. 4A-4G illustrate the new, ornamental design for the solar module of the energy-producing battery system 102′. FIG. 4A is a bottom plan view showing the new design; FIG. 4B is right side elevational view showing the new design; FIG. 4C is a from elevational t view showing the new design; FIG. 4D is a top plan view showing the new design, FIG. 4E is a rear elevational view showing the new design, FIG. 4F is a left side elevational view; and FIG. 4G is a perspective view.

FIGS. 5A-5G illustrate the new, ornamental design when cover of the energy-producing battery system 102′. FIG. 3A is a left side elevational view showing the new design; FIG. 5B is front elevational view showing the new design; FIG. 5C is a top plan view showing the new design; FIG. 5D is a rear elevational view showing the new design, FIG. 5E is a right side elevational view showing the new design, FIG. 5F is a bottom plan view; and FIG. 5G is a perspective view.

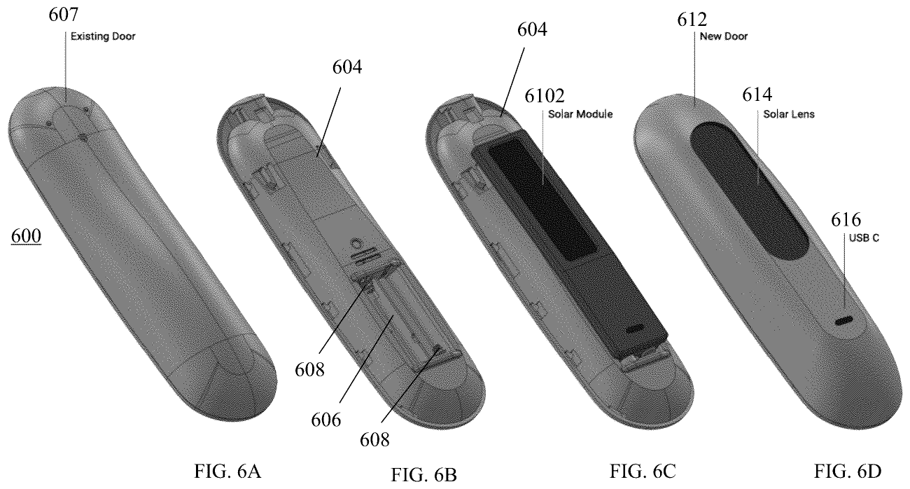

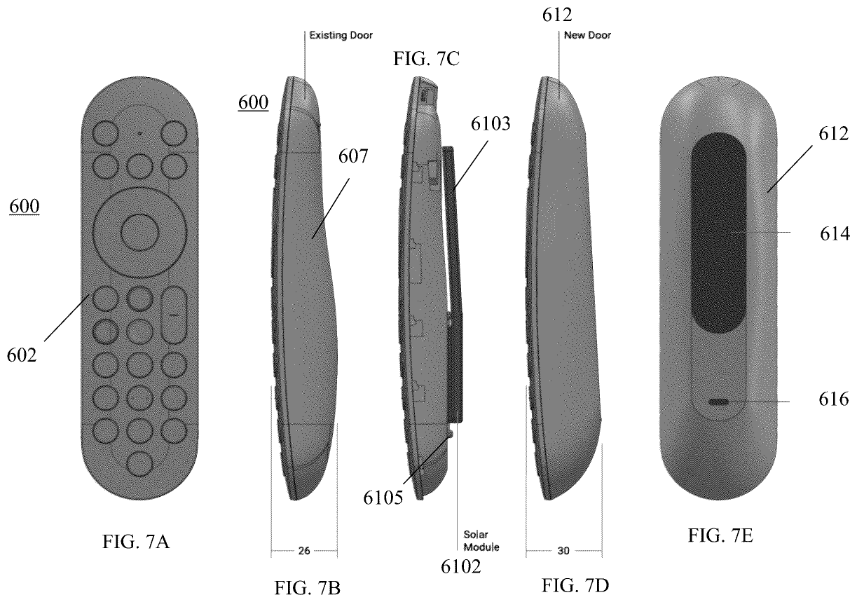

Turning to FIGS. 6A-6D and 7A-7E, a further example OEM remote control 600 is illustrated. As before, remote control 600 includes a front side 602 having input elements and a back side 604 having a battery storage compartment 606 with a corresponding cover or door 607 (shown engaged with the remote control main body in FIGS. 6B and 7B). The battery storage compartment 606 is arranged to hold two AA sized batteries in series configuration, meaning a positive terminal of one battery faces in the same direction as a negative terminal of the other battery. Spring elements 608 are provided within the battery storage compartment 606 to assist in maintaining the batteries with the battery compartment and to provide electrical connectivity with the electrical components with the remote control 600. The spring elements 608 are particularly used to engage with the negative, flat terminal of each battery.

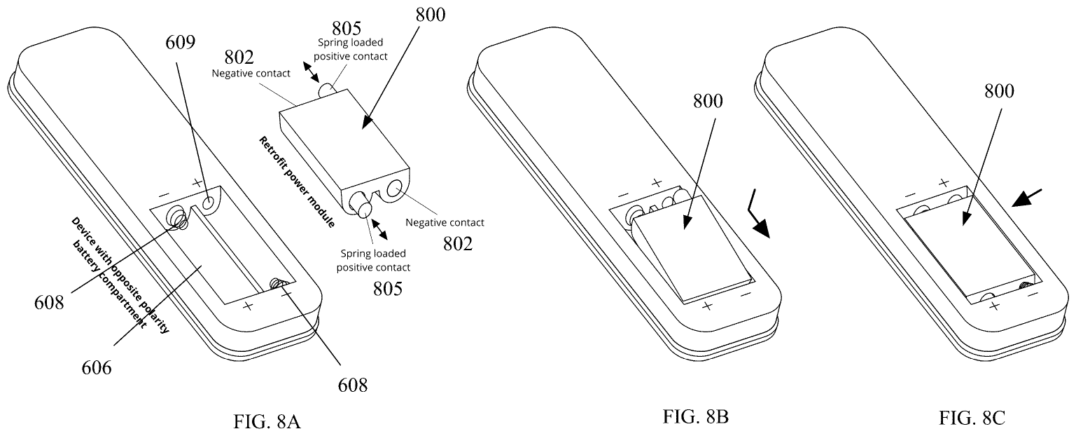

As further illustrated in FIGS. 6A-6D, and 7A-7E the batteries and original cover 607 may be replaced with an energy-producing, drop-in battery system 6102. In this example, the battery system 6102 includes one or more of the elements described previously with respect to energy-generating surface 104 and includes, as shown in FIGS. 8A-8C, a battery storage device 800 coupled to contacts 802. 803, 804, and 805 that are arranged to mate with corresponding contacts within the battery compartment 606 when the drop-in battery module 6102 is placed into the battery compartment 606. To facilitate engagement with the non-spring contacts 609 within the battery compartment 606, e.g., the positive contacts, contacts 803 and 805 are spring loaded or outwardly biased. In this manner, the battery storage device 800 would be partially inserted into the battery compartment 606 in a manner, such as on an angle, that functions to compress a one of the spring loaded contacts 803 or 805 and the corresponding spring element 608 as shown in FIG. 8B followed by placing the battery storage device 800 fully with the battery compartment whereupon the spring loaded contacts and elements would function to maintain the battery storage device 800 in position therewithin as shown in FIG. 8C.

Returning to FIGS. 6A-6D, and 7A-7E, in this illustrated example, the drop-in battery system 6102 includes a solar power energy collecting surface 6013 which is coupled to the battery storage device 800 as well as a USB-C port 6105 which is also connected to the battery storage device 800. The battery system 6012 is further held in place within the remote control 600 by use of a cover 612 that includes a transparent or translucent solar lens 614 that is desired to overlay the energy collecting surface 6013 and an opening 616 providing access to the USB-C port 6105. The cover 612 will include the same mating elements as the original cover 607 to thereby allow the cover 612 to mate with the remote control main body. The cover 612 may provide a tight fight with the module 6102 when the module 6102 is inserted into the compartment 606. The cover 612 may also be made of a somewhat flexible material to apply a biasing force upon the module 6102 when the module 6102 is inserted into the battery compartment 606. The cover 612 may also include biasing elements, such as a spring, wedge, cushion, or the like to apply a force upon the drop-in battery module 6102 in the direction of the battery compartment 606 if needed. As further shown, the drop-in battery system 6102 is larger than the battery compartment 606 in the illustrated example (as particularly shown in FIG. 7C) to maximize the light collecting surface 6103

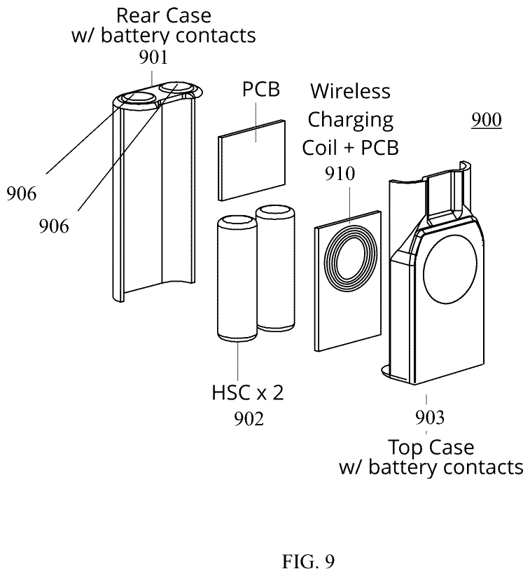

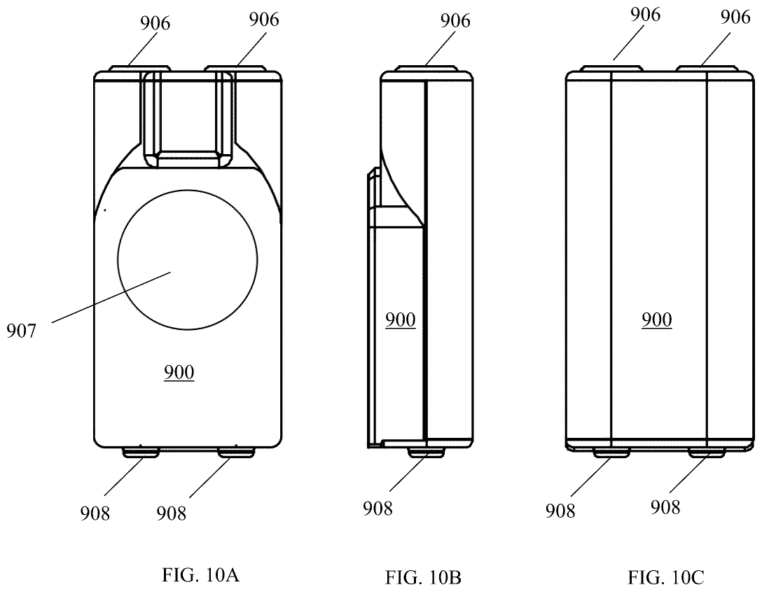

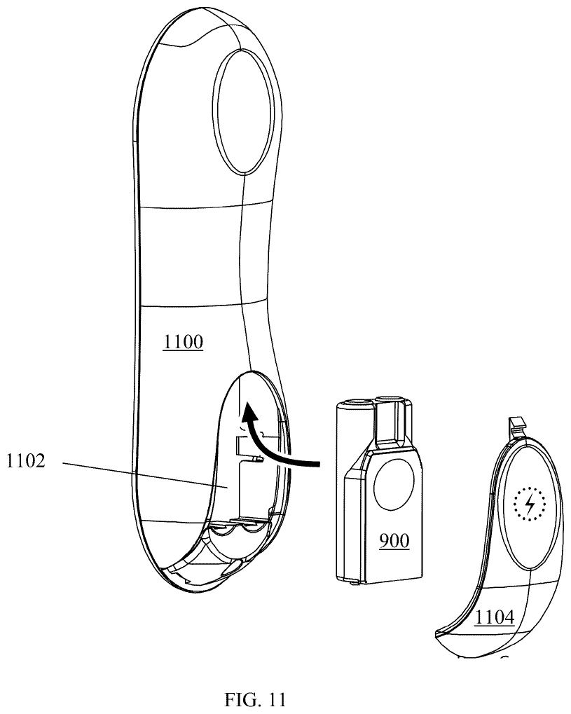

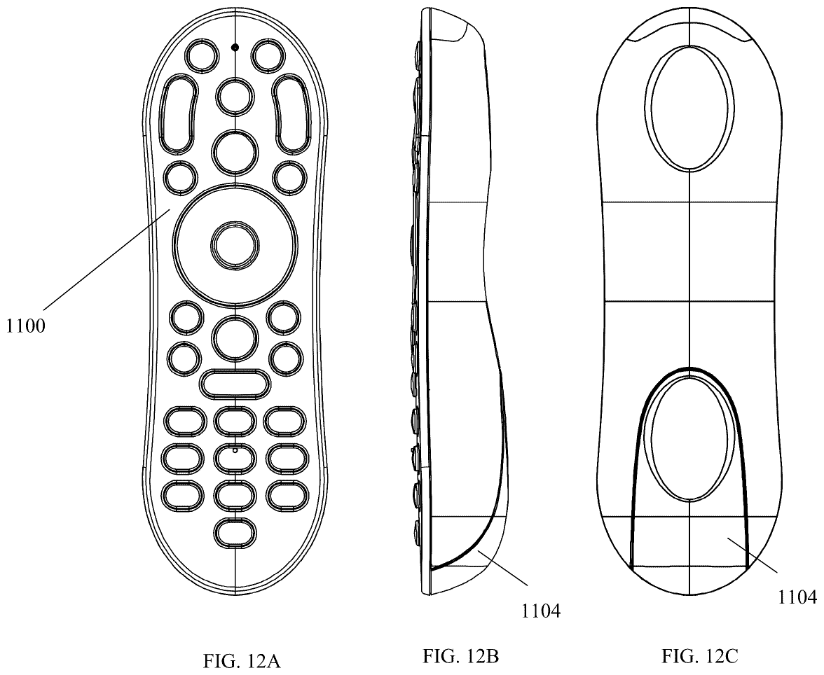

FIG. 9 illustrates an exploded view of another example battery replacement module 900. In this example, the battery replacement module includes a housing comprised of a bottom housing component 901 and top housing component 903. The housing is adapted to be fit into a battery compartment 1102 of an OEM remote control 1100 as shown in FIG. 11. In this example, the bottom housing component 901 includes contacts 906 for engaging with corresponding contacts within battery compartment 1102 while the top housing component 903 includes contacts 908 also for engaging with corresponding contacts within the battery compartment 1102 as shown in FIGS. 10A-10C. The contacts 906 and 908 are coupled to one or more energy storage devices 902 which are housed within the assembled housing and the one or more energy storage devices 902 are also coupled to an energy harvesting element 910. In the illustrated example, the energy harvesting element 910 comprises a wireless charging coil. Electrical components are additionally included within the battery replacement module to manage/control the electrical coupling between energy harvesting element 910 and the one or more energy storage devices 902 and between the one or more energy storage devices 902 and the contacts 906 and 908. The upper housing component 903 may include an opening 907 aligned with the energy harvesting element 910 so as, in this case, not to interfere with a charge provided by a recharging coil. As before, a cover 1104 is also provided as shown in FIGS. 11 and 12A-12C to make sure that the battery replacement module 900 remains secured within the battery compartment 1102 and the cover is sized, e.g., provided with a thickness, to ensure that the wireless charging coil can receive a charge.

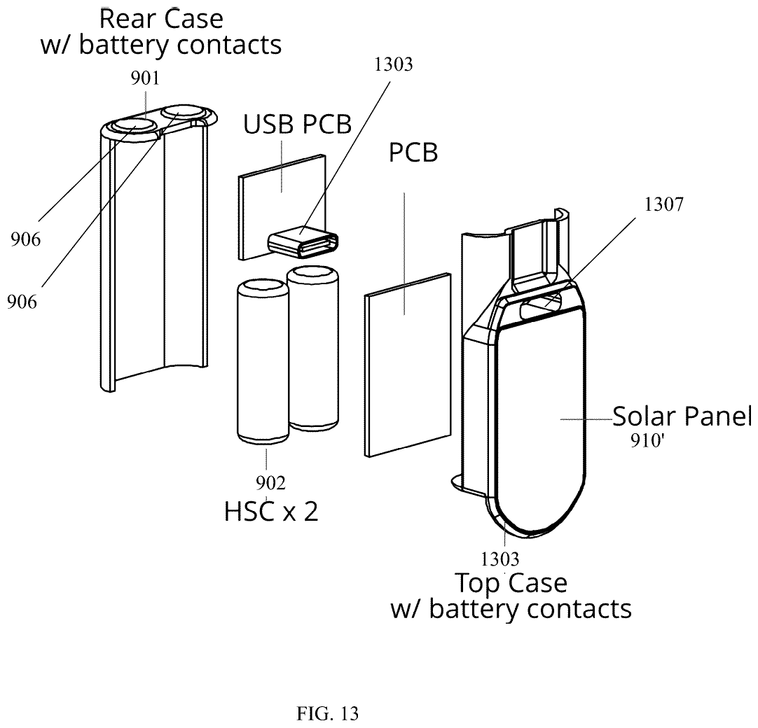

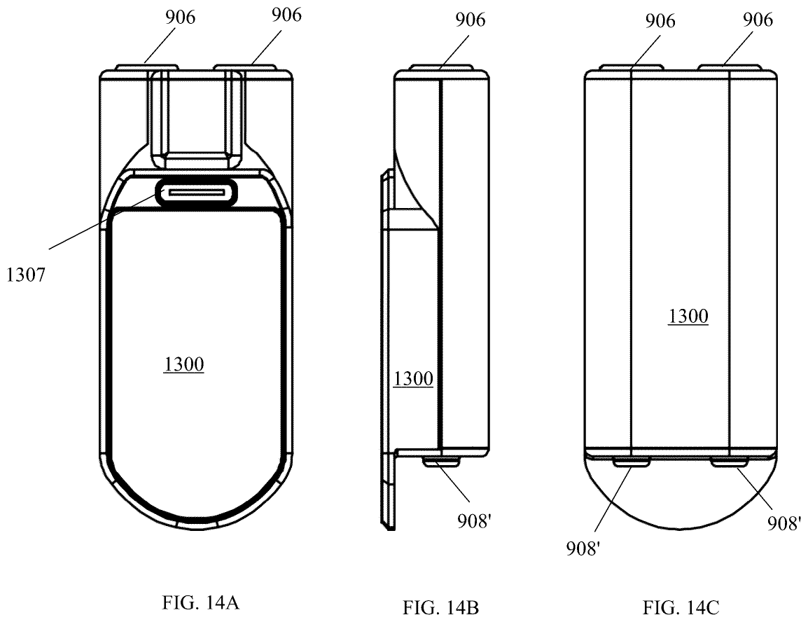

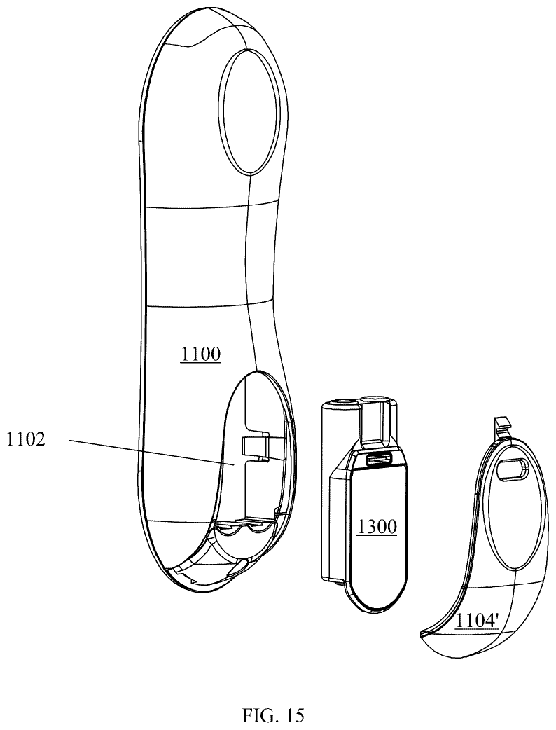

FIG. 13 illustrates an exploded view of yet another example battery replacement module 1300. In this example, the battery replacement module includes a housing comprised of the same bottom housing component 901 and a top housing component 1303. The housing is also adapted to be fit into the battery compartment 1102 of the OEM remote control 1100 as shown in FIG. 15. In this example, the bottom housing component 901 includes contacts 906 for engaging with corresponding contacts within battery compartment 1102 while the top housing component 1303 includes contacts 908′ also for engaging with corresponding contacts within the battery compartment 902 as shown in FIGS. 14A-14C. The contacts 906 and 908′ are coupled to one or more energy storage devices 902 which are housed within the assembled housing and the one or more energy storage devices 902 are also coupled to an energy harvesting element 910′. In the illustrated example, the energy harvesting element 910′ comprises a solar panel as described previously that is disposed on a top surface of the top component 1303. The top component 1303 additionally includes an opening 1307 providing access to a USB connector 1308. Electrical components are additionally included within the battery replacement module to manage/control the electrical coupling between energy harvesting element 910′ and the USB connector 1308 and the one or more energy storage devices 902 and between the one or more energy storage devices 902 and the contacts 906 and 908′. As before, a cover 1104′ is also provided as shown in FIGS. 15 to make sure that the battery replacement module 1300 remains secured within the battery compartment 1102. In this example, the cover 1104′ includes an opening 1106 which aligns with opening 1307 and a lens or window 1108 which overlays the solar panel.

In view of the foregoing, it will be understood that various examples have been described for replacing an existing battery cover and batteries with a substitute energy-producing battery system 102.

While various concepts have been described in detail, it will be appreciated by those skilled in the art that various modifications and alternatives to those concepts could be developed in light of the overall teachings of the disclosure. As such, the particular concepts disclosed are meant to be illustrative only and not limiting as to the scope of the invention which is to be given the full breadth of the appended claims and any equivalents thereof.

All documents cited within this application for patent are hereby incorporated by reference in their entirety.

What is claimed is:

1. A module for providing power to a battery-operated device having a body in which is formed a battery compartment and a cover having one or more first elements cooperable with one or more second elements provided to the body for releasably positioning the cover over the battery compartment, comprising:
an energy-generating surface;
an energy storage device coupled to the energy-generating surface, the energy storage device having one or more outwardly biased contact elements; and
a storage device cover positionable over the energy-generating surface having one or more third elements cooperable with the one or more second elements provided to the body for releasably positioning the module cover over the battery compartment when the energy storage device is positioned within the battery compartment with the one or more contact elements in engagement with a corresponding electrical contact positioned within the battery compartment for providing power to one or more electrical components of the battery-powered device.

2. The module as recited in claim 1, wherein the energy-generating surface comprises a photovoltaic (PV) active area and the storage device cover comprises a window that will be disposed over the PV active area when the storage device cover is placed into engagement with the body.

3. The module as recited in claim 2, wherein the window comprises one or more lens elements.

4. The module as recited in claim 1, wherein the first and third elements comprise a tongue and the second elements comprise a groove.

5. The module as recited in claim 1, wherein a size and shape of the energy-generating surface substantially matches a size and shape of the cover of the battery-operated device.

6. The module as recited in claim 1, wherein a size and shape of the energy generating surface extends past at least one dimension of the cover of the battery-operated device.

7. The module as recited in claim 1, wherein the cover provides a biasing force upon the energy-generating surface and the energy storage device in a direction towards a bottom surface of the battery compartment.

8. A combination comprising:
a battery-operated device having a body in which is formed a battery compartment and a cover having one or more first elements cooperable with one or more second elements provided to the body for releasably positioning the cover over the battery compartment; and
a module comprising:
an energy-generating surface;
an energy storage device coupled to the energy-generating surface having one or more outwardly biased contact elements; and
a storage device cover positionable over the energy-generating surface having one or more third elements cooperable with the one or more second elements provided to the body for releasably positioning the module cover over the battery compartment when the energy storage device is positioned within the battery compartment with the one or more outwardly biased contact elements in engagement with a corresponding electrical contact positioned within the battery compartment for providing power to one or more electrical components of the battery-powered device.

9. The combination as recited in claim 8, wherein the energy-generating surface comprises a photovoltaic (PV) active area and the storage device cover comprises a window that will be disposed over the PV active area when the storage device cover is placed into engagement with the body.

10. The combination as recited in claim 9, wherein the window comprises one or more lens elements.

11. The combination as recited in claim 8, wherein the first and third elements comprise a tongue and the second elements comprise a groove.

12. The combination as recited in claim 8, wherein a size and shape of the energy-generating surface substantially matches a size and shape of the cover of the battery-operated device.

13. The combination as recited in claim 8, wherein a size and shape of the energy generating surface extends past at least one dimension of the cover of the battery-operated device.

14. The combination as recited in claim 8, wherein the cover provides a biasing force upon the energy-generating surface and the energy storage device in a direction towards a bottom surface of the battery compartment.

15. The combination as recited in claim 8, wherein the energy storage device is coupled to a port for receiving power via use of a wired connection to an energy source.

16. The combination as recited in claim 15, wherein the port comprises a USB port.

17. The combination as recited in claim 15, wherein the module cover has an opening for providing access to the USB port when the module cover is engaged with the body.
